(19) United States
(12) Patent Application Publication
(10) Pub. No.: US 2026/0354257 A1
(43) Pub. Date: Nov. 5, 2026

(54) ELECTRONIC DEVICES AND METHODS OF MANUFACTURING ELECTRONIC DEVICES

(71) Applicant: Amkor Technology Singapore Holding Pte. Ltd.

(72) Inventors: In Soo Choi, Seoul (KR); Sang Hyun Jin, Incheon (KR); Ki Yeul Yang, Incheon (KR)

(73) Assignee: Amkor Technology Singapore Holding Pte. Ltd., (omitted)

(21) Appl. No.: 19/197,862

(22) Filed: May 2, 2025

(51) Int. Cl. H10W 74/10; H10W 40/25; H10W 70/09; H10W 70/60; H10W 72/00; H10W 90/00

(52) U.S. Cl. CPC H10W 74/137; H10W 40/25; H10W 70/60; H10W 72/011; H10W 74/121; H10W 90/00; H10W 70/09; H10W 90/734

(57) ABSTRACT

In one example, an electronic component is coupled to a contact and a first passivation disposed over the electronic component. The first passivation can define first openings partially through the first passivation and a second opening exposing the contact from the first passivation. A first seed can be disposed over the first passivation and in the first openings and the second opening. A first conductive material can be over the first seed in the first openings and second opening. A second seed can be disposed over an upper side of the first conductive material, and the first seed and second seed can encircle the first conductive material in the first openings and the second opening. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2K show an example method for manufacturing an electronic device using cross-sectional views.

FIGS. 3B to 3G show enlarged views of portion A in FIGS. 2B to 2G, respectively.

FIG. 4 shows a cross-sectional view of an example electronic device.

FIG. 5 shows a cross-sectional view of an example electronic device.

FIG. 6 shows a cross-sectional view of an example electronic device.

FIGS. 7A to 7E show an example method for manufacturing an electronic device using cross-sectional views.

FIG. 8 shows a cross-sectional view of an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein as labels to describe various elements, and these elements should not be limited by these terms. These terms are only used to distinguish one element from another. Thus, for example, a first element discussed in this disclosure could be termed a second element elsewhere without departing from the teachings of the present disclosure. Similarly, terms disclosed as singular can be plural in some embodiments, and elements disclosed as plural can be singular in some embodiments.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other, describe two elements indirectly coupled by one or more other elements, or two elements overlapping vertically as depicted. Unless specified otherwise, the term “coupled” can refer to a mechanical coupling or an electrical coupling.

### DESCRIPTION

An example electronic device can comprise an electronic component coupled to a contact, a first passivation can be disposed over the electronic component. The first passivation can define first openings partially through the first passivation and a second opening exposing the contact from the first passivation. A first seed can be disposed over the first passivation and in the first openings and the second opening. A first conductive material can be over the first seed in the first openings and second opening. A second seed can be disposed over an upper side of the first conductive material, and the first seed and second seed can encircle the first conductive material in the first openings and the second opening.

In various examples, the electronic device can include a second passivation disposed over the first passivation and defining a third opening that exposes the second see. A third seed can be coupled to the second seed and disposed over inner walls of the second passivation that define the third opening. A second conductive material can be disposed in the third opening, coupled to the third seed, and coupled to the second seed. A fourth seed can be disposed over the second conductive material and coupled to the third seed. The second seed, the third seed, and the fourth seed can encircle the second conductive material in the third opening. In some examples, an outer passivation can be disposed over the second passivation and can define a fourth opening that exposes the fourth seed from the outer passivation. An outward terminal can be disposed in the fourth opening and coupled to the fourth seed. A portion of the first seed can extend out from the first openings and over an upper side of the first passivation around the first openings.

In some examples, the portion of the first seed extending over the upper side of the first passivation comprises a width from 0.1 micrometers (μm) to 1.5 μm. The second seed completely covers an upper side of the first conductive material. The second seed extends from an upper side of the first conductive material onto an upper side of the first seed. The first seed and the second seed comprise titanium. The first seed and the second seed surrounding the first conductive material can comprise a four-sided barrier. The first conductive material can comprise an embedded trace disposed in the first passivation and covered by a second passivation. The first seed further comprises an inner seed including titanium or titanium tungsten coupled to the first passivation, to inner walls defining the first openings and the second opening, and to the contact. An outer seed can include copper, aluminum, nickel, gold, or silver coupled to the inner seed and can covering the inner seed. The first conductive material is coupled to the outer seed. The upper side of the first conductive material can be recessed from an upper side of the first passivation. The second seed over the upper side of the first conductive material is disposed in the first openings. An encapsulant can be coupled to the electronic component and can include a side coplanar with a side of the first passivation. Sidewalls of the electronic component can be coplanar with sidewalls of the first passivation. An underfill can be disposed between the electronic component and the first passivation. A thermal interface material can be coupled to the electronic component and a lid coupled to the thermal interface material.

An example method of manufacturing an electronic device can include the steps of providing an electronic component coupled to a contact, and providing a first passivation over the electronic component and the contact. The first passivation can define a first opening extending partially through the first passivation and a second opening exposing the contact from the first passivation. The steps can further include providing a first seed over the first passivation and in the first opening and the second opening, providing a first conductive material over the first seed in the first openings and second opening, and providing a second seed over an upper side of the first conductive material. The first seed and second seed can encircle the first conductive material in the first openings and second opening.

Another example electronic device can comprise an electronic component, a first passivation disposed over the electronic component and defining an opening, and a first seed disposed over the first passivation and in the opening defined by the first passivation. A portion of the first seed is coupled to the first passivation around a perimeter of the opening. A conductive material can be disposed over the first seed in the opening. A second seed can cover an upper side of the conductive material and can be coupled to the portion of the first seed. The first seed and second seed can encircle the conductive material.

Other examples are included in the present disclosure. Such examples may be found in the figures, in the claims, or in the description of the present disclosure.

Electronic devices and related methods can comprise conductive elements resistant to oxidation. In some examples, a conductive element such as a trace or pad can be surrounded by a barrier. For example, a titanium barrier layer can completely encircle a cross section of a copper conductive element, resulting in a 4-face or all-sided, metallic-barrier structure. The barrier can comprise a two-piece or multiple-piece barrier structure. For example, a barrier layer can be formed, then a conductive element can be formed over the barrier layer with an exposed side, then a second barrier layer can be formed over the exposed side of the conductive element to surround the conductive element. In some examples, the barrier layers described herein can be applied to embedded traces (ETR).

In some examples, a four-sided barrier (e.g., encircling a conductive element) can reduce oxidation compared to a three-sided barrier (e.g., with one side of the conductive element exposed from the barrier). Some examples of four-sided barriers can result in a reduction in oxidation area ratio (e.g., oxidation area/conductive element area×100) in conductive elements by a factor of approximately 14, approximately 15, or approximately 16 (e.g., 15.53 in some examples) or approximately 17, approximately 18, or approximately 19 (e.g., 18.92 in some examples) compared to conductive elements lacking barriers on one or on three sides, respectively. Examples of four-sided barriers can also mitigate increased resistance over time that can result from oxidation of conductive elements. For example, four-sided barriers can limit increases in resistance of a conductive element over time by a factor of approximately 23, approximately 24, or approximately 25 (e.g., 23.78 in some examples), or approximately 62, approximately 63, or approximately 64 (e.g., 63.69 in some examples) compared to conductive elements lacking a barrier on one or on three sides, respectively. Reliability of electronic devices can thus be improved by using a four-sided barrier.

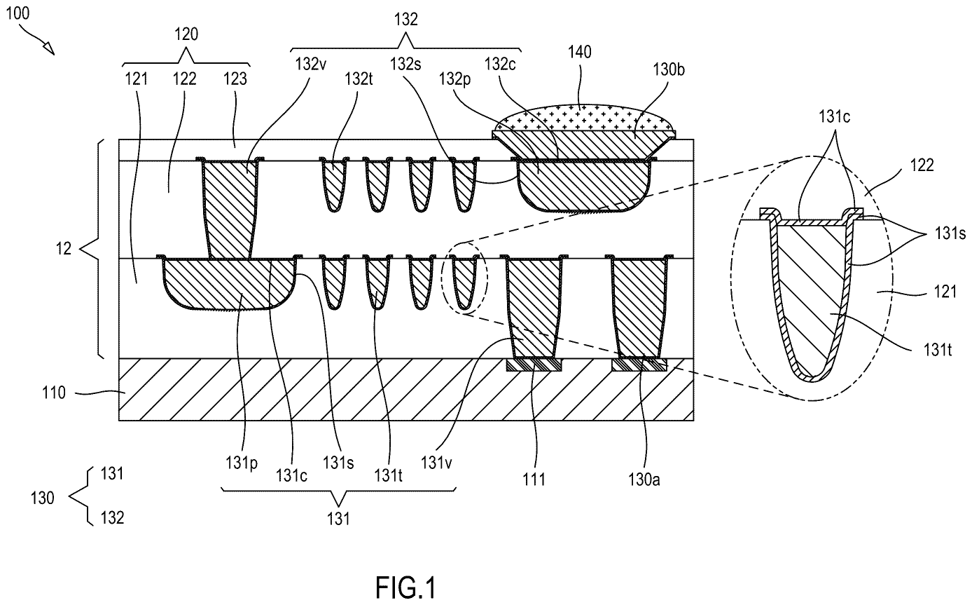

Referring now to FIG. 1, a cross-sectional view of example electronic device 100 is shown, in accordance with various examples. In the example shown in FIG. 1, electronic device 100 comprises electronic component 110 and substrate 12. Substrate 12 comprises dielectric structure 120 and conductive structure 130. In some examples, electronic device 100 can also include interconnects 140.

In accordance with various examples, dielectric structure 120 can comprise passivation 121, passivation 122, and outer passivation 123. Conductive structure 130 can comprise conductive pattern 131 and conductive pattern 132. Conductive pattern 131 can comprise capping seed 131c, seed 131s, traces 131t, pads 131p, and vias 131v. Conductive pattern 132 can comprise capping seed 132c, seed 132s, traces 132t, pads 132p and vias 132v. Seed 131s and capping seed 131c can comprise a four-sided barrier in some examples. Conductive structure 130 can comprise inward terminals 130a and outward terminals 130b. Inward terminals 130a can be coupled to contacts 111 of electronic component 110.

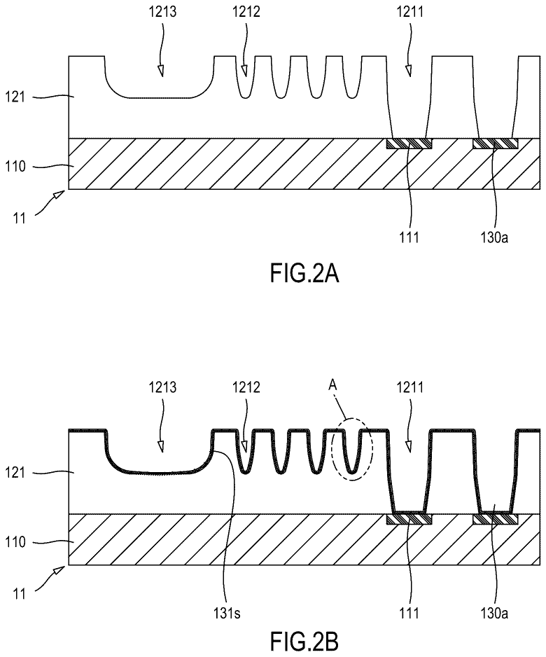

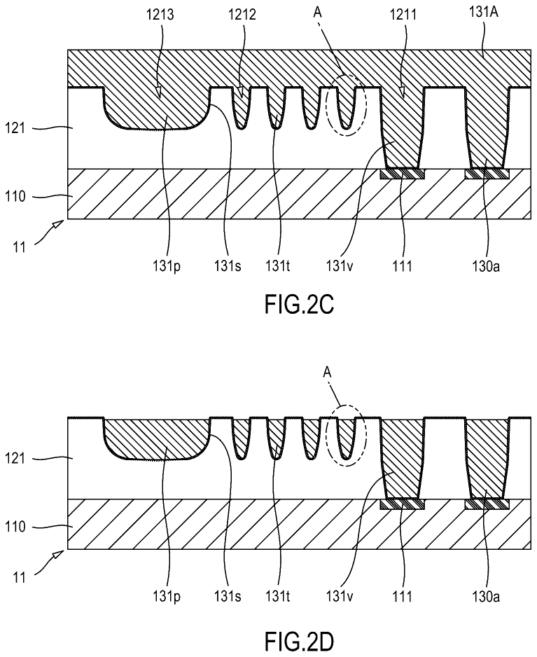

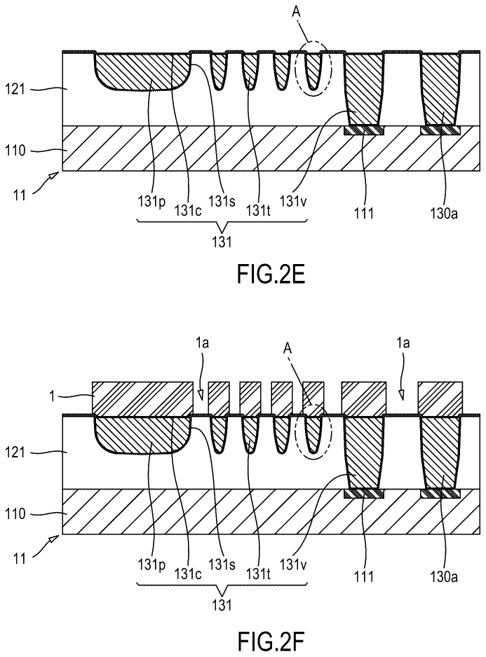

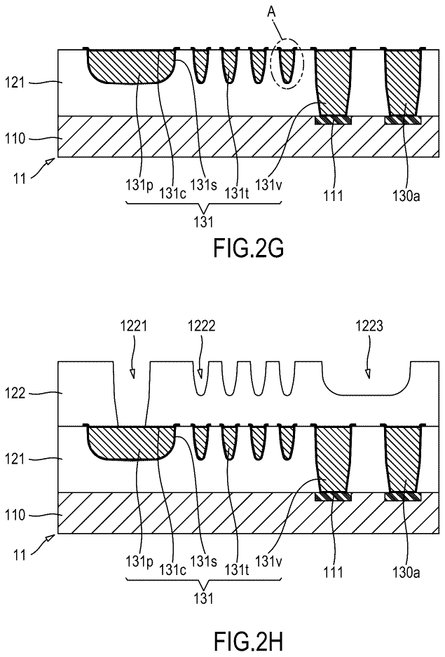

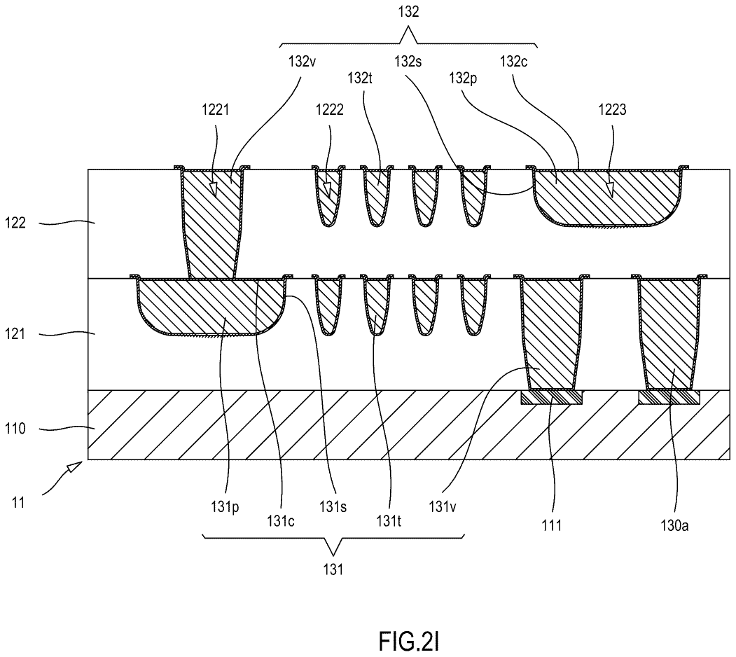

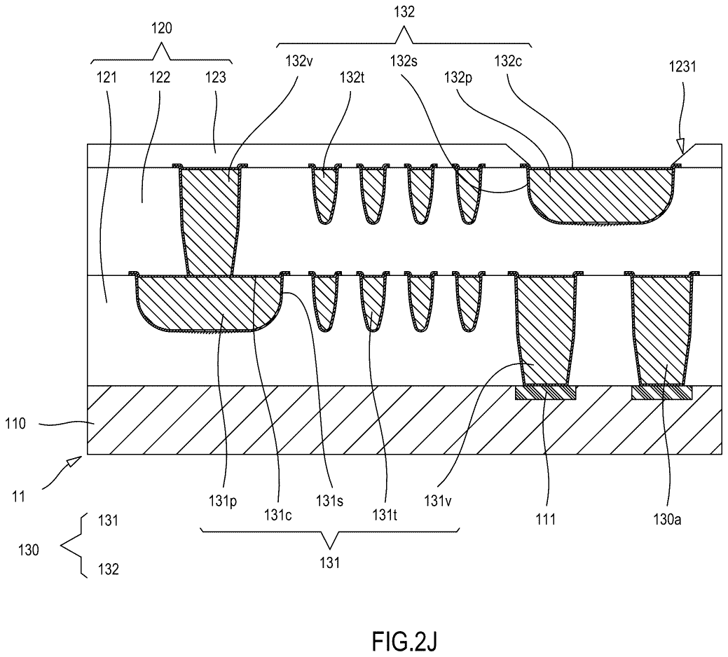

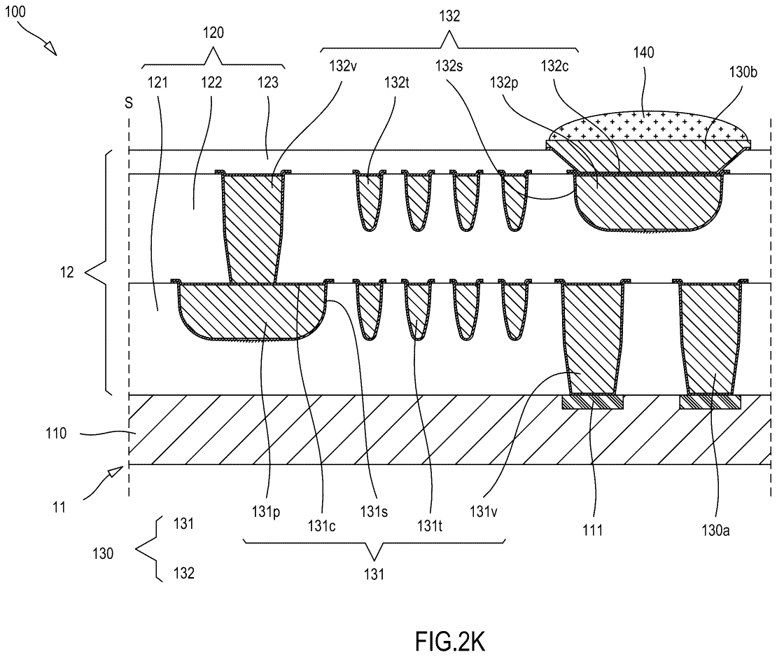

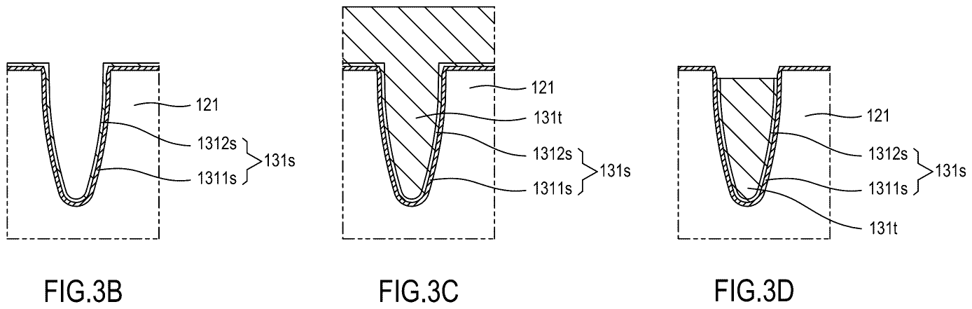

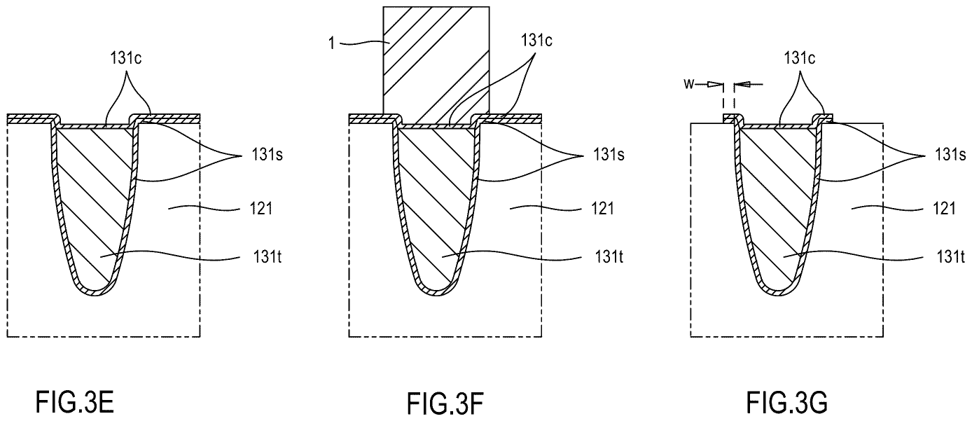

FIGS. 2A to 2K show cross-sectional views of an example method for manufacturing an electronic device, such as electronic device 100 of FIG. 1. FIGS. 3B to 3G show enlarged views of portion A in FIGS. 2B to 2G, respectively.

FIG. 2A shows a cross-sectional view of electronic device 100 at an early stage of manufacture. In the example shown in FIG. 2A, passivation 121 can be provided on electronic component 110. Electronic component 110 can comprise or be referred to as a semiconductor die, a semiconductor chip, or package. For example, electronic component 110 can comprise a digital signal processor, network processor, power management unit, audio processor, radio-frequency circuit, wireless baseband system-on-chip (SoC) processor, sensor, or application specific integrated circuit (ASIC). In some examples, electronic component 110 can be configured to perform calculations, control processing, store data, or remove noise from electrical signals.

In some examples, electronic component 110 can comprise contacts 111. Contacts 111 can be disposed over an active side of electronic component 110. Contacts 111 can comprise or be referred to as pads, lands, UBMs (Under Bump Metals), studs, bumps, or pillars.

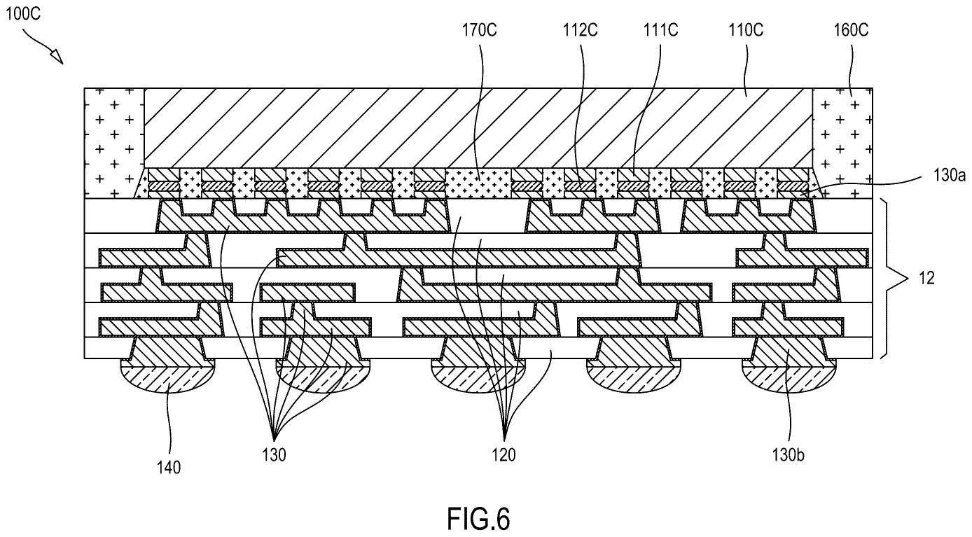

In accordance with various examples, electronic component 110 can be part of a substrate 11. In some examples, substrate 11 can comprise or be referred to as a wafer, a reconstituted wafer, or a panel. For example, substrate 11 can be a semiconductor wafer including electronic components 110 formed in rows and columns across the wafer and separated by saw streets. In some examples, substrate 11 can be a reconstituted wafer including known good electronic components 110 arranged in rows and columns with encapsulant located between adjacent known good electronic components 110. In some examples, substrate 11 can be a panel including one or more semiconductor wafers and/or reconstituted wafers located thereon. The thickness of substrate 11 can range from about 50 micrometers (μm) to about 2000 μm. The terms about, approximately, or similar terms as used with numeric values can mean +/−5%, +/−10%, +/−15%, +/−20%, or+/−25%. In some examples, substrate 11 can be a temporary carrier, as discussed below with reference to FIG. 6A.

In accordance with various examples, passivation 121 can be provided to cover the upper side of substrate 11. Passivation 121 can be formed by physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), spin coating, spray coating, dip coating, rod coating, or any other suitable deposition process.

Passivation 121 can be patterned to provide one or more openings 1211, trace grooves 1212, and pad grooves 1213 in passivation 121. Openings 1211 can extend completely through passivation 121 and can expose contacts 111. Trace grooves 1212 and pad grooves 1213 can be formed partially through passivation 121, such that a portion of passivation 121 remains over electronic component 110 and comprises a floor of trace grooves 1212 and pad grooves 1213. The layout and shape of trace grooves 1212 and pad grooves 1213 are selected to form the desired conductive structures (e.g., traces, pads, ground planes, etc.) of conductive pattern 131 (FIG. 2B).

In some examples, passivation 121 can be patterned by providing a patterned mask (e.g., a patterned photoresist) on the upper side of passivation 121. Portions of passivation 121 exposed from the mask are then removed (i.e., passivation 121 can be patterned) to form openings 1211, trace grooves 1212, and pad grooves 1213. The mask is removed after passivation 121 is patterned.

In some examples, passivation 121 can comprise or be referred to as a dielectric, dielectric layer, insulator, or insulating layer. For example, passivation 121 can comprise one or more layers of an electrical insulating material, such as an organic dielectric (e.g., polymer, polyimide (Pl), benzocyclobutene (BCB), polybenzoxazole (PBO), bismaleimide triazine (BT)) or an inorganic dielectric (e.g., silicon nitride (Si3N4), silicon oxide (SiO2), or silicon oxynitride (SiON)). In some examples, the thickness of passivation 121 can range from about 2 μm to about 20 μm.

FIG. 2B shows a cross-sectional view of electronic device 100 at a later stage of manufacture. FIG. 3B shows enlarged views of portion A in FIG. 2B. In the example shown in FIGS. 2B and 3B, seed 131s can be provided over passivation 121. Seed 131s can be located in openings 1211, trace grooves 1212, and pad grooves 1213. For example, seeds 131s can be provided over the upper surface of passivation 121, the sidewalls and floors of openings 1211, trace grooves 1212, pad grooves 1213, and along the exposed upper side of contacts 111. Seeds 131s can be formed by electroless plating, electrolytic plating, sputtering, PVD, CVD, MOCVD, ALD, LPCVD, PECVD, or any other suitable deposition process.

Seed 131s can comprise an inner seed 1311s and an outer seed 1312s. In some examples, outer seed 1312s can be provided by forming inner seed 1311s covering the upper side of passivation 121. For example, inner seed 1311s can be provided over the upper most surface of passivation 121, the sidewalls and floors of openings 1211, trace grooves 1212, pad grooves 1213, and along the exposed upper side of contacts 111. Outer seed 1312s can be provided to cover the inner seed 1311s. Inner seed 1311s can comprise titanium (Ti) or titanium tungsten (TiW). Outer seed 1312s can comprise copper (Cu), aluminum (Al), nickel (Ni), gold (Au) or silver (Ag). In some examples, the thickness of seed 131s can range from about 0.01 μm to about 1 μm.

FIG. 2C shows a cross-sectional view of electronic device 100 at a later stage of manufacture. FIG. 3C shows enlarged views of portion A in FIG. 2C. In the example shown in FIGS. 2C and 3C, electrically conductive material 131A can be provided over seed 131s. Electrically conductive material 131A can be located in, fill, or partially fill openings 1211, trace grooves 1212, and pad grooves 1213. In some examples, conductive pattern 131 can be provided by forming seeds 131s covering the upper side of passivation 121.

Electrically conductive material 131A can be provided over outer seed 1312s by electroless plating, electrolytic plating, sputtering, PVD, CVD, MOCVD, ALD, LPCVD, PECVD, or any other suitable deposition. Electrically conductive material 131A can comprise metals (e.g., Cu, Al, Au, Ag, or Ni), alloys, compounds, or other conductive materials. The electrically conductive material 131A can be part of the conductive pattern 131. Outer seed 1312s can comprise materials similar to or the same as those described for electrically conductive material 131A.

In accordance with various examples, the portions of conductive material 131A that are located in openings 1211 can be coupled to contacts 111 of electronic component 110 and can comprise or be referred to as vias 131v. The portions of conductive material 131A located at the floor of openings 1211 (i.e., at the bottom sides of vias 131v) can be referred to as substrate inward terminals 130a. In some examples, one or more of the trace grooves 1212 and the portions of conductive material 131A located in the trace grooves 1212 can comprise and/or form one or more ground planes.

FIG. 2D shows a cross-sectional view of electronic device 100 at a later stage of manufacture. FIG. 3D shows enlarged views of portion A in FIG. 2D. In the example shown in FIGS. 2D and 3D, electrically conductive material 131A disposed outside of openings 1211, trace grooves 1212, and pad grooves 1213 can be removed.

In some examples, chemical mechanical planarization (CMP) can be used to remove electrically conductive material 131A from over the upper most surface of outer seed 1312s. Electrically conductive material 131A can fill or partially fill openings 1211, trace grooves 1212, and pad grooves 1213, respectively, and outer seed 1312s can be exposed. Electrically conductive material 131A disposed in openings 1211, trace grooves 1212, and pad grooves 1213, respectively, can comprise or be referred to as vias 131v, traces 131t, and pads 131p.

In various examples, outer seed 1312s can be removed by etching (e.g., wet etching or dry etching) to expose inner seed 1311s. When outer seed 1312s is removed, the upper side of vias 131v, traces 131t, and pads 131p can also be partially removed. For example, the upper side of vias 131v, traces 131t, and pads 131p can be recessed with respect to the upper side of inner seed 1311s. Outer seed 1312s can be comprise material similar to or the same as vias 131v, traces 131t, or pads 131p. Outer seed 1312s positioned in openings 1211, trace grooves 1212, and pad grooves 1213 can be considered parts of vias 131v, traces 131t, and pads 131p, respectively. Outer seed 1312s of FIG. 3D is omitted from some figures depicting subsequent processing steps for simplicity (e.g., FIGS. 3E-3G) , though it should be understood that outer seed 1312s can be present in the examples of subsequent figures even where not depicted. Seed 131s can comprise or be referred to as inner seed 1311s herein. Conductive pattern 131 can comprise vias 131v, traces 131t, and pads 131p. The thickness of vias 131v, traces 131t, and pads 131p can range from about 1 μm to about 20 μm.

FIG. 2E shows a cross-sectional view of electronic device 100 at a later stage of manufacture. FIG. 3E shows enlarged views of portion A in FIG. 2E. In the example shown in FIGS. 2E and 3E, capping seed 131c can be provided over seed 131s, vias 131v, traces 131t, and pads 131p. Capping seed 131c can be provided to cover to the upper side of seed 131s, the upper side of vias 131v, traces 131t, and pads 131p. Capping seed 131c covering the upper side of vias 131v, traces 131t, and pads 131p can be positioned lower than (e.g., recessed from) the capping seed 131c covering the upper side of seed 131s. Capping seed 131c can be formed by electroless plating, electrolytic plating, sputtering, PVD, CVD, MOCVD, ALD, LPCVD, PECVD, or any other suitable deposition process. Capping seed 131c can be made of a similar material to a seed layer. For example, capping seed 131c can comprise titanium (Ti) or titanium tungsten (TiW). In some examples, the thickness of capping seed 131c can range from about 0.01 μm to about 1 μm.

FIG. 2F shows a cross-sectional view of electronic device 100 at a later stage of manufacture. FIG. 3F shows enlarged views of portion A in FIG. 2F. In the example shown in FIGS. 2F and 3F, mask 1 is provided over capping seed 131c. In some examples, mask 1 can comprise a photoresist. Mask 1 can be patterned using various techniques such as, for example, exposure, development, etching, and curing to form mask openings 1a. Mask openings 1a can expose portions of capping seed 131c. Mask openings 1a can expose portions of seed 131s located on passivation 121. Mask 1 can cover portions of capping seeds 131c located on vias 131v, traces 131t and pads 131p. In some examples, the width or diameter of mask 1 can be greater than the width or diameter of vias 131v, traces 131t, and pads 131p, such that mask 1 also cover portions of capping seed 131c located on the upper side of passivation 121.

FIG. 2G shows a cross-sectional view of electronic device 100 at a later stage of manufacture. FIG. 3G shows enlarged views of portion A in FIG. 2G. In the example shown in FIGS. 2G and 3G, capping seed 131c and seed 131s exposed through mask openings 1a can be removed. For example, capping seed131c and seed 131s can be removed through etching (e.g., wet etching or dry etching) to a portion of the uppermost side of passivation 121. Capping seed131c and seed 131s can cover portions of the uppermost side of passivation 121, and are adjacent to vias 131v, traces 131t, and pads 131p. Capping seed 131c and seed 131s can extend toward the uppermost side of passivation 121 from edges of vias 131v, traces 131t, and pads 131p. The width (w) of capping seed 131c and seed 131s extending over passivation 121 around the perimeter openings or grooves in passivation 121 can range from about 0.1 μm to about 1.5 μm.

In some examples, vias 131v, traces 131t, and pads 131p can comprise or be referred to as an embedded trace RDL. Vias 131v, traces 131t, and pads 131p can be surrounded or encircled by capping seed 131c and seed 131s. Each capping seed 131c or seed 131s can function as a protective layer for protecting vias 131v, traces 131t, and pads 131p, thereby preventing moisture from penetrating into vias 131v, traces 131t, and pads 131p. Capping seed 131c and seed 131s comprise a barrier layer that can prevent or inhibit oxidation of vias 131v, traces 131t, and pads 131p. Capping seed 131c and seed 131s serving as a barrier can thus improve electrical properties by limiting decay or atrophy of conductive pattern 131 that might otherwise result from oxidation or moisture penetration.

FIG. 2H shows a cross-sectional view of electronic device 100 at a later stage of manufacture. In the example shown in FIG. 2H, passivation 122 can be provided on conductive pattern 131 and passivation 121. In some examples, passivation 122 can be provided covering conductive pattern 131 and passivation 121. Portions of passivation 122 can be removed (i.e., passivation 122 can be patterned) to form openings 1221, trace grooves 1222, and pad grooves 1223. Trace grooves 1222, pad grooves 1223, and openings 1221 can be formed by etching (e.g., wet etching or dry etching), laser ablation, or any other suitable patterning process. In accordance with various examples, trace grooves 1222 can extend partially through passivation 122, and a portion of passivation 122 remains over passivation 121 and conductive pattern 131 and forms a floor of trace grooves 1222 and pad grooves 1223. Openings 1221 can extend completely through passivation 122 and can expose portions of conductive pattern 131. In some examples, passivation 121 can comprise or be referred to as a dielectric, dielectric layer, insulator, or insulating layer. In some examples, passivation 122 can include elements, features, materials, or manufacturing methods similar to or the same as those described for passivation 121.

FIG. 2I shows a cross-sectional view of electronic device 100 at a later stage of manufacture. In the example shown in FIG. 2I, conductive pattern 132 can be provided over passivation 122 and conductive pattern 131. Conductive pattern 132 can be disposed in, fill, or partially fill openings 1221, trace grooves 1222, and pad grooves 1223. Conductive pattern 132 can comprise elements, features, materials, or manufacturing methods similar to or the same as those of conductive pattern 131.

In various examples, conductive pattern 132 disposed in openings 1221, trace grooves 1222, and pad grooves 1223, respectively, can comprise or be referred to as vias 132v, traces 132t and pads 132p. Vias 132v can be contacted and electrically connected to expose portions of conductive pattern 131. For example, exposed portions of conductive pattern 131 can be pads 131p of conductive pattern 131.

In some examples, vias 132v, traces 132t, and pads 132p can comprise or be referred to as an embedded trace RDL. Vias 132v, traces 132t, and pads 132p can be covered by the capping seed 132c and seed 132s, respectively. Capping seed 132c and seed 132s can function as protective layers for protecting vias 132v, traces 132t, and pads 132p, thereby preventing moisture from penetrating into vias 132v, traces 132t, and pads 132p. Capping seed 132c and seed 132s can prevent or inhibit oxidized of vias 132v, traces 132t, and pads 132p.

FIG. 2J shows a cross-sectional view of electronic device 100 at a later stage of manufacture. In the example shown in FIG. 2J, outer passivation 123 can be provided on conductive pattern 132 and passivation 122. In some examples, outer passivation 123 can be provided by covering conductive pattern 132 and passivation 122. Portions of outer passivation 123 can be removed (i.e., outer passivation 123 can be patterned) to form apertures 1231. Pads 132p of conductive pattern 132 can be exposed apertures 1231. Apertures 1231 can be formed by etching (e.g., wet etching or dry etching), laser ablation, or any other suitable patterning process. In some examples, outer passivation 123 can have elements, features, materials, or manufacturing methods similar to those of passivation 121. In some examples, outer passivation 123 can comprise or be referred to as a dielectric, dielectric layer, insulator, or insulating layer. In some examples, outer passivation 123 can comprise or be referred to as a solder resist.

FIG. 2K shows a cross-sectional view of electronic device 100 at a later stage of manufacture. In the example shown in FIG. 2K, outward terminals 130b can be provided in apertures 1231 of outer passivation 123, and interconnects 140 can be provided on outward terminals 130b.

In accordance with various examples, outward terminal 130b can fill or partially fill apertures 1231 of outer passivation 123. Outward terminals 130b are coupled to and can contact pads 132p of conductive pattern 132. In accordance with various examples, the elements, features, materials, or manufacturing methods of outward terminals 130b can be similar to or the same as those of conductive pattern 131 or conductive pattern 132. For example, outward terminals 130b can be formed by electroless plating, electrolytic plating, sputtering, PVD, CVD, MOCVD, ALD, LPCVD, PECVD, or any other suitable deposition process and can comprise conductive material such as Cu, Al, Au, Ag, or Ni. Outward terminals 130b can include a seed similar to or the same as seed 131s of conductive pattern 131.

Interconnects 140 can be coupled to outward terminals 130b. In some examples, interconnects 140 can comprise tin (Sn), Ag, lead (Pb), Cu, Sn—Pb, Sn37—Pb, Sn95—Pb, Sn—Pb—Ag, Sn—Cu, Sn—Ag, Sn—Au, Sn—Bi, or Sn—Ag—Cu. For example, interconnects 140 can be provided by forming a conductive material including solder on outward terminals 130b through a ball drop and reflow process. In some examples, interconnects 140 may also include under bump metals (UBMs) formed between the bump and outward terminal 130b. Interconnects 140 can comprise or be referred to as conductive balls such as solder balls, conductive pillars such as copper pillars, or conductive posts with a solder cap formed on a copper pillar. In some examples, interconnects 140 can be referred to as external input/output terminals of electronic device 100. In some examples, electronic device 100 can be a land grid array (LGA) with component outward terminals 130b serving as external input/output terminals of electronic device 100 (i.e., electronic device 100 can be devoid of interconnects 140).

In accordance with various examples, dielectric structure 120 and conductive structure 130 can form substrate 12. In some examples, substrate 12 can be referred to as an RDL substrate, build-up substrate, build-up RDL, or build-up signal distribution structure. Although conductive structure 130 is shown as having a total of three layers including conductive pattern 131, conductive pattern 132, and outward terminals 130b, the number of conductive pattern layers can be fewer or greater than three, and any suitable number of conductive pattern layers can be included in electronic device 100.

In accordance with various examples, after interconnects 140 are provided, a singulation process can be performed to separate substrate 11 into individual electronic devices 100. The singulation process can include sawing through substrate 12 and between adjacent electronic components 110 (e.g., sawing through saw streets S). The singulation process can utilize a blade, laser beam, or any other suitable cutting means. After singulation, the lateral sides of substrate 12 can be coplanar with the lateral sides of electronic component 110.

In electronic device 100, conductive pattern 132 can be covered, encircled, or otherwise surrounded by capping seed 132c and seed 132s. Capping seed 132c and seed 132s can thus serve as a four-sided barrier to inhibit moisture penetration into and oxidation of conductive pattern 132. Capping seed 132c and seed 132s serving as a barrier can thus improve electrical properties by limiting decay or atrophy of conductive pattern 132 over time.

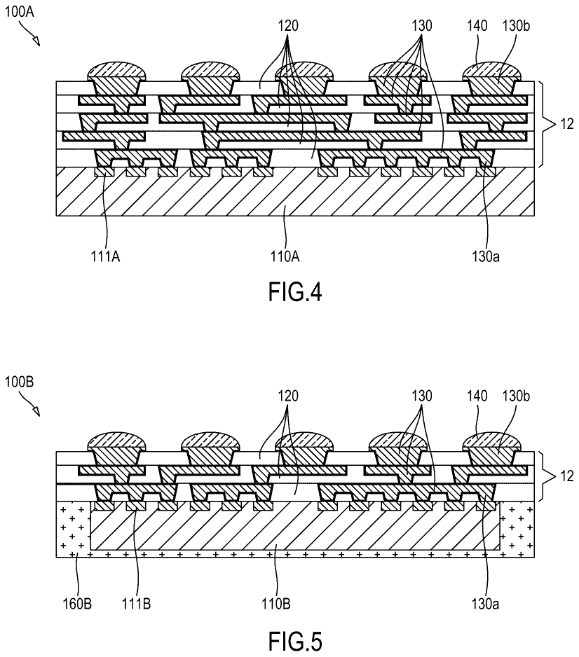

FIG. 4 shows a cross-sectional view of an example electronic device 100A. In the example shown in FIG. 4, electronic device 100A can comprise electronic component 110A, substrate 12, and interconnects 140. Electronic component 110A includes component interconnects 111A. Substrate 12 includes dielectric structure 120 and conductive structure 130. In some examples, electronic device 100A can be manufactured using techniques and structures similar to or the same as those shown in FIGS. 2A to 2K or described herein.

Electronic device 100A, as depicted in the example of FIG. 4, can include multiple layers of conductive structure 130 interleaved with multiple layers of dielectric structure 120. In some examples, electronic device 100A can comprise or be referred to as a wafer level package (WLP) or wafer level chip scale package (WLCSP).

FIG. 5 shows a cross-sectional view of an example electronic device 100B. In the example shown in FIG. 5, electronic device 100B comprises electronic component 110B, substrate 12, interconnects 140, and encapsulant 160B. Substrate 12 includes dielectric structure 120 and conductive structure 130. Electronic component 110B can comprise component interconnects 111B. Electronic device 100B shown in FIG. 5 can be similar to or the same as electronic device 100A shown in FIG. 4, with encapsulant 160B provided around electronic device 100B.

Electronic device 100B can be manufactured using techniques, processes, and structures similar to or the same as those shown in FIGS. 2A to 2K or described herein. For example, substrate 11 of FIGS. 2A to 2K can comprise a reconstituted wafer having encapsulant 160B provided between adjacent electronic components 110B. In some examples, singulation, as shown in FIG. 2K, can take place through encapsulant 160B, and after singulation, encapsulant 160B is coplanar with substrate 12.

In some examples, encapsulant 160B can comprise or be referred to as a package body, an encapsulating structure, a mold, an epoxy molding compound, a resin, a filler-reinforced polymer, a B-stage compressed film, or gel. Encapsulant 160B can be provided by transfer molding, compression molding, liquid encapsulant molding, vacuum lamination, paste printing, film assisted molding, or other suitable processes. In some examples, encapsulant 160B can contact or cover a bottom side or lateral side of electronic component 110B. In some examples, the bottom side of encapsulant 160B and the bottom side of electronic component 110B can be coplanar, and the bottom side of electronic component 110B can be exposed from the bottom side of encapsulant 160B. Encapsulant 160B can protect electronic component 110B from the external environment or from environmental exposure.

In some examples, substrate 12 can be provided on the top side of encapsulant 160B and on the top side of electronic component 110B. In some examples, the top side of electronic component 110B and the top side of encapsulant 160B can be coplanar. In some examples, electronic device 100B can comprise or be referred to as a wafer level fan-out (WLFO).

FIG. 6 shows a cross-sectional view of an example electronic device 100C. In the example shown in FIG. 6, electronic device 100C can comprise electronic component 110C, substrate 12, interconnects 140, and encapsulant 160C. In some examples, electronic device 100C can also include underfill 170C. Substrate 12 includes dielectric structure 120 and conductive structure 130. Electronic device 100C shown in FIG. 6 can be similar to or the same as electronic devices 100A and 100B shown in FIGS. 4 and 5, respectively, with dielectric structure 120 and conductive structure 130 of electronic device 100C provided prior to coupling electronic component 110C to substrate 12 and prior to providing encapsulant 160C.

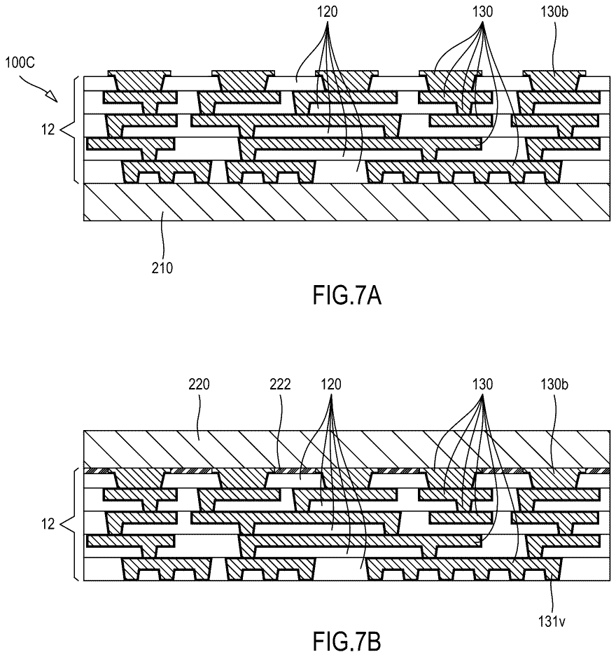

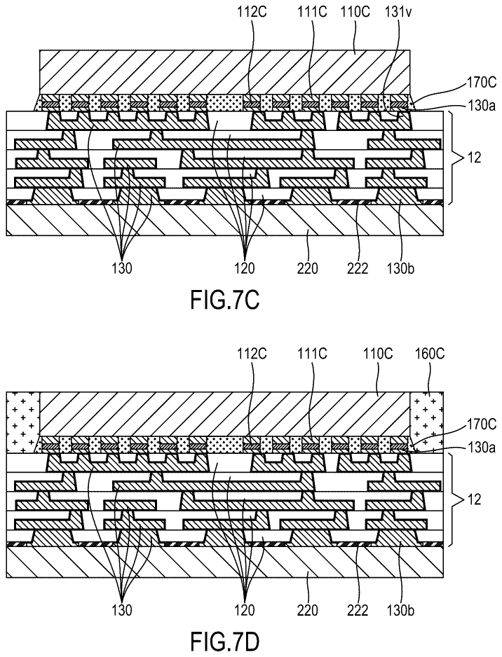

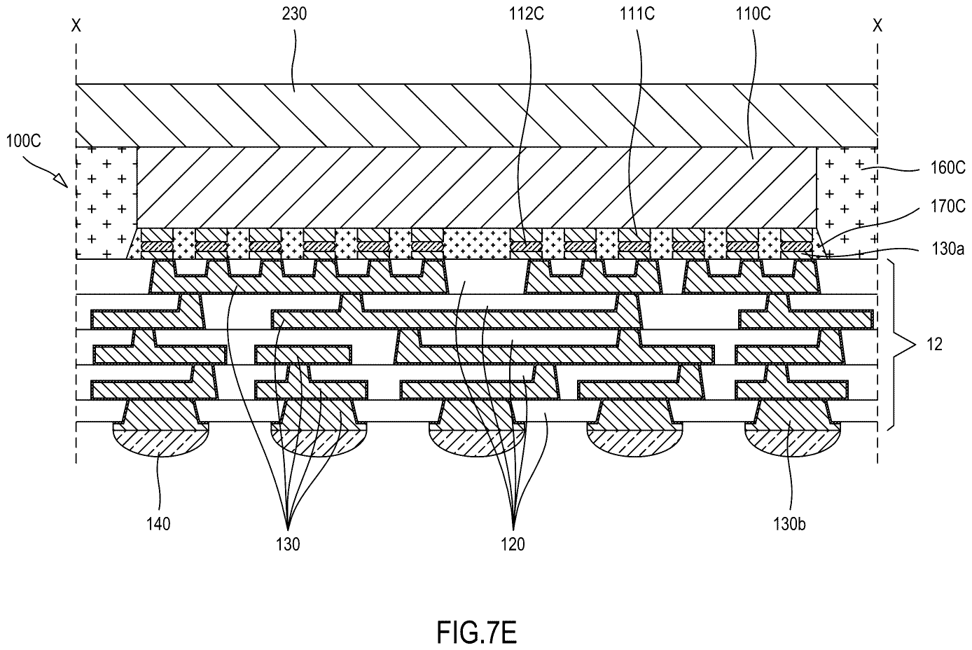

With reference to FIGS. 7A to 7E, an example method for manufacturing an electronic device 100C is shown, in accordance with various examples. FIG. 7A shows a cross-sectional view of electronic device 100C at an early stage of manufacture. In the example shown in FIG. 7A, substrate 12, including dielectric structure 120 and conductive structure 130, can be provided on carrier 210. In accordance with various examples, substrate 12 can be provided over carrier 210 using techniques and structures similar to or the same as those shown in FIGS. 2A to 2K or described herein.

In some examples, carrier 210 can comprise or be referred to as a wafer, plate, panel, strip, substrate, or temporary carrier. Carrier 210 can comprise semiconductor material (e.g., Si), glass, metal, ceramic, etc. In some examples, a temporary adhesive can be provided on the upper side of carrier 210 to facilitate the separation of substrate 12 from carrier 210. The temporary adhesive can be, for example, a heat release tape (or film) or an optical release tape (or film), configured to have its adhesive strength reduced by heat or light, respectively.

FIG. 7B shows a cross-sectional view of electronic device 100C at a later stage of manufacture. In the example shown in FIG. 7B, support carrier 220 is coupled to an upper side of substrate 12 and carrier 210 is removed from the opposite side of substrate 12.

In various examples, support carrier 220 can comprise or be referred to as a wafer, plate, panel, strip, substrate, or temporary carrier. Support carrier 220 can comprise semiconductor material (e.g., Si), glass, metal, ceramic, etc. In some examples, a temporary adhesive 222 can be provided on support carrier 220 to facilitate the separation of substrate 12 from support carrier 220. Temporary adhesive 222 can be, for example, a heat release tape (or film) or an optical release tape (or film), configured to have its adhesive strength reduced by heat or light, respectively. In some examples, outer passivation 123 of dielectric structure 120 and outward terminals 130b of conductive structure 130 can be coupled to temporary adhesive 222.

In accordance with various examples, carrier 210 (FIG. 7A) can be removed from substrate 12 by grinding, etching, laser ablation, physical force, application of heat or light, or another suitable removal method. Removal of carrier 210 exposes a bottom side of conductive vias 131v and passivation of dielectric structure 120. In some examples, removal of carrier 210 can expose inward terminals 130a of conductive structure 130. In other examples, and as shown in FIG. 6C, inward terminals 130a can be provided after removal of carrier 210.

FIG. 7C shows a cross-sectional view of electronic device 100C at a later stage of manufacture. In the example shown in FIG. 7C, substrate 12 can be flipped, relative to the view shown in FIG. 7B, and electronic component 110C can be provided over substrate 12. While substrate 12 is shown as being coupled to a second carrier 220 and flipped in the example of FIG. 7C to facilitate coupling electronic component 112C to earlier-formed layers or structures of substrate 12, in other examples substrate 12 can remain on carrier 210 and/or in the same orientation as FIG. 7A and electronic component 110C can be coupled to later-formed layers or structures (e.g., outward terminals 130b to which interconnects 140 are coupled can be formed first on carrier 210 in FIG. 7A and inward terminals 130a to electronic component 110C is coupled can formed last and/or distal to carrier 210).

In various examples, electronic component 110C can comprise or be referred to as a die, chip, package (e.g., one or more die in an encapsulant and/or coupled to a laminate substrate or RDL substrate), or passive element. In some examples, the thickness of electronic component 110C can range from about 20 μm to about 100 μm.

In accordance with various examples, electronic component 110C can be coupled to conductive structure 130. Electronic component 110C can comprise contacts 111C and component interconnects 112C in contact with contacts 111C. For example, component interconnects 112C of electronic component 110C can be coupled to inward terminals 130a of conductive structure 130. In electronic component 110C, contacts 111C can be electrically connected to inward terminals 130a through component interconnects 112C. Contacts 111C can comprise or be referred to as bumps, pads, or pillars. In some examples, the thickness of contacts 111C can range from about 1 μm to about 10 μm. Component interconnects 112C can comprise or be referred to as solder. In some examples, component interconnect 112C can be electrically coupled to inward terminals 130a by thermocompression bonding, ultrasonic bonding, laser assisted bonding, or hybrid bonding (e.g., the interconnection between contacts 111C and inward terminal 130a can lack component interconnects 112C). In some examples, the elements, features, materials, or manufacturing methods of inward terminals 130a can be similar to or the same as those of conductive pattern 131 shown in FIGS. 2A to 2E or described herein.

In accordance with various examples, underfill 170C can be provided between substrate 12 and electronic component 110C. In some examples, underfill 170C can contact substrate 12 (e.g., dielectric structure 120 or conductive structure 130), contacts 111C, component interconnects 112C, and electronic component 110C. In some examples, underfill 170C can comprise or be referred to as capillary underfill, non-conductive paste, or non-conductive film. In some examples, underfill 170C can be urged into a gap between electronic component 110C and substrate 12 after electronic component 110C is electrically coupled to substrate 12. In some examples, underfill 170C can be pre-coated onto substrate 12 prior to electronic component 110C being coupled to substrate 12. In some examples, underfill 170C can be pre-coated on electronic component 110C prior to electronic component 110C being coupled to substrate 12. In some examples, a curing process (e.g., a thermal curing process or a photocuring process) can be performed on underfill 170C.

FIG. 7D shows a cross-sectional view of electronic device 100C at a later stage of manufacture. In the example shown in FIG. 7D, encapsulant 160C is provided over electronic component 110C and substrate 12. In some examples, encapsulant 160C can cover or be coupled to substrate 12, electronic component 110C, and underfill 170C. In some examples, underfill 170C can be omitted, and encapsulant 160C can be filled between electronic component 110C and substrate 12. In some examples, encapsulant 160C can be removed from over the backside of electronic component 110C. For example, the backside of electronic component 110C can be exposed from encapsulant 160C. In some examples, the backside of electronic component 110C and encapsulant 160C can be coplanar. In some examples, encapsulant 160C can cover the backside of electronic component 110C. Elements, features, materials, or manufacturing methods of encapsulant 160C can be similar to or the same as those of encapsulant 160B.

FIG. 7E shows a cross-sectional view of electronic device 100C at a later stage of manufacture. In the example shown in FIG. 7E, support 230 can be coupled to encapsulant 160C and electronic component 110C, and support carrier 220 can be removed from substrate 12.

In accordance with various examples, support 230 can comprise or be referred to as a wafer, plate, panel, strip, substrate, tape, or temporary carrier. In some examples, a temporary adhesive can be provided on the upper side of support 230 to facilitate the separation of support 230 from electronic device 100C. The temporary adhesive can be, for example, a heat release tape (or film) or an optical release tape (or film), configured to have its adhesive strength reduced by heat or light.

In accordance with various examples, support carrier 220 (FIG. 7D) can be removed from substrate 12 by grinding, etching, laser ablation, physical force, application of heat and/or light, or another suitable removal method. Removal of support carrier 220 exposes outward terminals 130b and outer passivation of dielectric structure 120. Interconnects 140 can be provided on outward terminals 130b, as described above.

In accordance with various examples, after interconnects 140 are provided, a singulation process can be performed to separate substrate 12 with electronic components 110C coupled thereto into individual electronic devices 100C. The singulation process can include sawing through substrate 12 and encapsulant 160C (e.g., sawing along saw lines X). The singulation process can utilize a blade, laser beam, or any other suitable cutting means. After singulation, the lateral sides of substrate 12 can be coplanar with the lateral sides of encapsulant 160C. In some examples, the singulation process can remove encapsulant 160C from the lateral sides of electronic component 110C, such that after singulation, the lateral sides of substrate 12 are coplanar with the lateral sides of electronic component 110C.

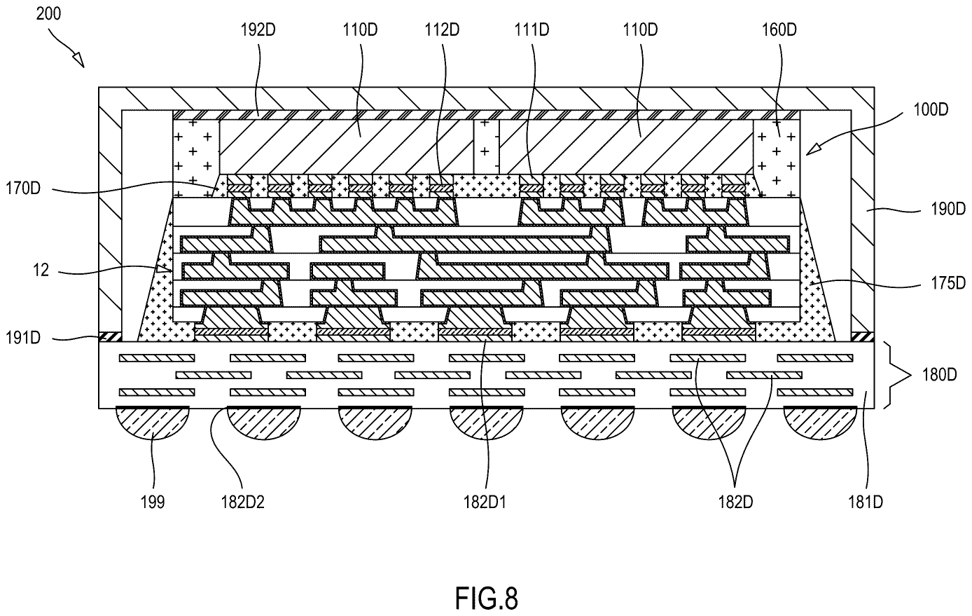

FIG. 8 shows a cross-sectional view of an example electronic device 200. In the example shown in FIG. 8, electronic device 200 can comprise electronic device 100D, underfill 175D, base substrate 180D, external interconnect 199, and body 190D. Electronic device 100D can be coupled to base substrate 180D and can comprise electronic components 110D, substrate 12, contacts 111D, component interconnects 112D, interconnects 140, encapsulant 160D, and underfill 170D. Substrate 12 can include dielectric structure 120 and conductive structure 130. In accordance with various examples, electronic device 100D can be similar to electronic device 100C in FIG. 6 and can be provided as shown in FIGS. 7A to 7E.

In accordance with various examples, interconnects 140 of electronic device 100D are coupled to base substrate 180D. Base substrate 180D can comprise dielectric structure 181D and conductive structure 182D. In some examples, dielectric structure 181D can comprise dielectric layers. The dielectric layers can comprise one or more layers of dielectric materials interleaved with the layers of the conductive structures. In some examples, the dielectric materials can comprise Pl, BCB, PBO, resin, or Ajinomoto Buildup Film (ABF). In some examples, conductive structure 182D can comprise one or more conductive layers defining signal distribution elements (e.g., traces, vias, pads, conductive paths, or UBM). Conductive structure 182D can comprise substrate inward terminal 182D1 and substrate outward terminal 182D2. In some examples, substrate inward terminal 182D1 can comprise pads, lands, UBM, or studs. In some examples, substrate outward terminals 182D2 can comprise pads or lands. External interconnects 199 can comprise solder balls, bumps, pads, or pillars. In some examples, electronic device 200 can be an LGA (e.g., external interconnects 199 can be omitted).

In some examples, base substrate 180D can be a pre-formed substrate. The pre-formed substrate can be manufactured prior to attachment to an electronic device and can comprise dielectric layers between respective conductive layers. The conductive layers can comprise copper and can be formed using an electroplating process. The dielectric layers can be relatively thicker non-photo-definable layers and can be attached as a pre-formed film rather than as a liquid and can include a resin with fillers such as strands, weaves, and/or other inorganic particles for rigidity and/or structural support. Since the dielectric layers are non-photo-definable, features such as vias or openings can be formed by using a drill or laser. In some examples, the dielectric layers can comprise a prepreg material or ABF. The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate and omit the permanent core structure, and the dielectric and conductive layers can be formed on a sacrificial carrier that is removed after formation of the dielectric and conductive layers and before attachment to the electronic device. The pre-formed substrate can rereferred to as a printed circuit board (PCB) or a laminate substrate. Such pre-formed substrates can be formed through a semi-additive or modified-semi-additive process. Other substrates described herein can also comprise a pre-formed (or laminate) substrate.

In some examples, substrate 180D can be an RDL substrate. RDL substrates can comprise one or more conductive redistribution layers and one or more dielectric layers and (a) can be formed layer by layer over an electronic device to which the RDL substate is electrically coupled, or (b) can be formed layer by layer over a carrier that can be entirely removed or partially removed after the electronic device and the RDL are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly stacked with one or more conductive layers that define respective conductive redistribution pattern or traces configured to collectively (a) fan-out electrical traces outside the footprint of the electronic device, and/or (b) fan-in electrical traces within the footprint of the electronic device. The conductive pattern can be formed using a plating process such as, for example, an electroplating process or an electroless plating process. The conductive pattern can comprise an electrically conductive material such as, for example, copper or other plateable metal. The locations of the conductive pattern can be made using a photopatterning process such as, for example, a photolithography process and a photoresist material to form a photolithographic mask.

The dielectric layers of the RDL substrates can be patterned with a photopatterning process and can include a photolithographic mask through which light is exposed to photo-pattern desired features, such as vias in the dielectric layers. The dielectric layers can be made from photo-definable organic dielectric materials such as, for example, polyimide (Pl), benzocyclobutene (BCB), or polybenzoxazole (PBO). Such dielectric materials can be spun on or otherwise coated in liquid form, rather than attached as a pre-formed film. To permit proper formation of desired photo-defined features, such photo-definable dielectric materials can omit structural reinforcers or can be filler-free, without strands, weaves, or other particles, and can interfere with the light from the photopatterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrate can comprise one or more inorganic dielectric layers. Some examples of inorganic dielectric layers can comprise silicon nitride (Si3N4), silicon oxide (SiO2), and/or SiON. The inorganic dielectric layers can be formed by growing the inorganic dielectric layers using an oxidation or nitridization process instead of using photo-defined organic dielectric materials. Such inorganic dielectric layers can be filler-fee, without strands, weaves, or other dissimilar inorganic particles. In some examples, RDL substrates can omit the permanent core or carrier structure generally associated with laminate substrates (e.g., RDL substrate can be devoid of a dielectric/core material comprising bismaleimide triazine (BT) or FR4). These types of RDL substrates can be referred to as coreless substrates. Other substrates described herein can also comprise an RDL substrate.

Interconnects 140 of electronic device 100D can be electrically coupled to substrate inward terminal 182D1 of base substrate 180D. In some examples, interconnects 140 can be electrically coupled to substrate inward terminal 182D1 by thermal compression bonding, ultrasonic bonding, laser assisted bonding, or hybrid bonding. In some examples, solder can be interposed between interconnects 140 and substrate inward terminal 182D1. In some examples, underfill 175D can be interposed between substrate 12 and base substrate 180D. Elements, features, materials, or manufacturing methods of underfill 175D can be similar to, or the same as, those of underfill 170C.

In some examples, body 190D can be coupled through adhesive material 191D to substrate 180D, and can be coupled through interface material 192D to electronic components 110D. In some examples, interface material 192D can also be interposed between encapsulant 160D and body 190D. Interface material 192D can comprise or be referred to as thermal interface material (TIM) (e.g., a metallic TIM or polymer TIM), an adhesive, or a backside metallization. Body 190D can comprise or be referred to as a heat spreader, lid, cover, case, shield, or housing. In some examples, Body 190D can comprise a metal or metal alloy (e.g., Cu, Al, Ni, Ag, etc.). In some examples, the thickness of body 190D can range from about 10 μm to about 100 μm. Body 190D can dissipate heat from electronic components 110D, shield electronic component 110D from electromagnetic interference, and/or protect substrate 12 and electronic component 110D from the external environment.

Electronic devices and related methods can include barrier layers or barriers surrounding conductive elements. For example, traces, pads, vias, or other conductive elements can be encircled or surrounded by seed layers that form a barrier. The barrier can inhibit or prevent oxidation or moisture penetration that can otherwise break down or damage conductive elements over time. Seed layers of the present disclosure that form a four-sided barrier can improve electrical performance of conductive elements over time relative to three-sided or other less protective examples of barriers for conductive elements.

The present disclosure includes reference to certain examples, however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device comprising:
an electronic component coupled to a contact;
a first passivation disposed over the electronic component, the first passivation defining first openings partially through the first passivation and a second opening exposing the contact from the first passivation;
a first seed disposed over the first passivation and in the first openings and the second opening;
a first conductive material disposed over the first seed in the first openings and second opening; and
a second seed disposed over an upper side of the first conductive material, wherein the first seed and second seed encircle the first conductive material in the first openings and the second opening.

2. The electronic device of claim 1, further comprising:
a second passivation disposed over the first passivation and defining a third opening that exposes the second seed;
a third seed coupled to the second seed and disposed over inner walls of the second passivation that define the third opening;
a second conductive material disposed in the third opening, coupled to the third seed, and coupled to the second seed; and
a fourth seed disposed over the second conductive material and coupled to the third seed, wherein the second seed, the third seed, and the fourth seed encircle the second conductive material in the third opening.

3. The electronic device of claim 2, further comprising:
an outer passivation disposed over the second passivation and defining a fourth opening that exposes the fourth seed from the outer passivation; and
an outward terminal disposed in the fourth opening and coupled to the fourth seed.

4. The electronic device of claim 1, wherein a portion of the first seed extends out from the first openings and over an upper side of the first passivation around the first openings.

5. The electronic device of claim 4, wherein the portion of the first seed extending over the upper side of the first passivation comprises a width from 0.1 micrometers (μm) to 1.5 μm.

6. The electronic device of claim 1, wherein the second seed completely covers an upper side of the first conductive material.

7. The electronic device of claim 1, wherein the second seed extends from an upper side of the first conductive material onto an upper side of the first seed.

8. The electronic device of claim 1, wherein the first seed and the second seed comprise titanium.

9. The electronic device of claim 1, wherein the first seed and the second seed surrounding the first conductive material comprise a four-sided barrier, and wherein the first conductive material comprises an embedded trace disposed in the first passivation and covered by a second passivation.

10. The electronic device of claim 1, wherein the first seed further comprises:
an inner seed including titanium or titanium tungsten coupled to the first passivation, to inner walls defining the first openings and the second opening, and to the contact; and
an outer seed including copper, aluminum, nickel, gold, or silver coupled to the inner seed and covering the inner seed, wherein the first conductive material is coupled to the outer seed.

11. The electronic device of claim 1, wherein the upper side of the first conductive material is recessed from an upper side of the first passivation.

12. The electronic device of claim 1, wherein the second seed over the upper side of the first conductive material is disposed in the first openings.

13. The electronic device of claim 1, further comprising an encapsulant coupled to the electronic component, the encapsulant including a side coplanar with a side of the first passivation.

14. The electronic device of claim 1, wherein sidewalls of the electronic component are coplanar with sidewalls of the first passivation.

15. The electronic device of claim 1, further comprising an underfill disposed between the electronic component and the first passivation.

16. The electronic device of claim 1, further comprising a thermal interface material coupled to the electronic component and a lid coupled to the thermal interface material.

17. A method of manufacturing an electronic device, comprising:
providing an electronic component coupled to a contact;
providing a first passivation over the electronic component and the contact, the first passivation defining a first opening extending partially through the first passivation and a second opening exposing the contact from the first passivation;
providing a first seed over the first passivation and in the first opening and the second opening;
providing a first conductive material over the first seed in the first openings and second opening; and
providing a second seed over an upper side of the first conductive material, wherein the first seed and second seed encircle the first conductive material in the first openings and second opening.

18. The method of claim 17, further comprising:
providing a second passivation over the first passivation, the second passivation defining a third opening exposing the second seed;
providing a third seed disposed over inner walls of the second passivation and coupled to the second seed;
providing a second conductive material disposed in the third opening, coupled to the third seed, and coupled to the second seed; and
providing a fourth seed disposed over the second conductive material and coupled to the third seed, wherein the second seed, the third seed, and the fourth seed encircle the second conductive material in the third opening.

19. The method of claim 18, further comprising:
providing an outer passivation over the second passivation and defining a fourth opening exposing the fourth seed; and
providing an outward terminal in the fourth opening and coupled to the fourth seed.

20. An electronic device comprising:
an electronic component;
a first passivation disposed over the electronic component and defining an opening;
a first seed disposed over the first passivation and in the opening defined by the first passivation, wherein a portion of the first seed is coupled to the first passivation around a perimeter of the opening;
a conductive material disposed over the first seed in the opening; and
a second seed covering an upper side of the conductive material and coupled to the portion of the first seed, wherein the first seed and second seed encircle the conductive material.
